(19) United States
(12) Patent Application Publication
(10) Pub. No.: US 2024/0295690 A1
(43) Pub. Date: Sep. 5, 2024

(54) HERMETICALLY-COVERED PHOTONIC INTEGRATED CIRCUIT (PIC) ON A SUBSTRATE HAVING AN INTEGRATED LASER DIODE

(71) Applicant: Meta Platforms Technologies, LLC, Menlo Park, CA (US)

(72) Inventors: Dusan COSO, Bothell, WA (US); Steven Alexander-Boyd Hickman, Seattle, WA (US); Giuseppe Calafiore, Woodinville, WA (US); Petr Markov, Stateline, NV (US); Shermin Arab, East Palo Alto, CA (US); John Michael Goward, Oxford (GB); Rahul Agarwal, Woodinville, WA (US); Zhujun Shi, Redmond, WA (US)

(73) Assignee: Meta Platforms Technologies, LLC, Menlo Park, CA (US)

(21) Appl. No.: 18/441,693

(22) Filed: Feb. 14, 2024

Related U.S. Application Data
(60) Provisional application No. 63/449,686, filed on Mar. 3, 2023.

(51) Int. Cl. G02B 6/12

(52) U.S. Cl. CPC G02B 6/12; G02B 2006/12121

(57) ABSTRACT

According to examples, an apparatus for implementing a hermetically-covered photonic integrated circuit on a substrate having an integrated laser diode is described. The apparatus may include a cover wafer, a housing layer including a waveguide, the waveguide including a photonic integrated circuit, a laser die including a laser cavity, and a base substrate. The base substrate may include an emission window to provide a reflective design and to eliminate a need for a polarized beam splitter, a through-wafer via element to electrical coupling to the laser die and one or more pillars to set a height of the laser die relative to the photonic integrated circuit.

### PRIORITY

This patent application claims priority to U.S. Provisional Patent Application No. 63/449,686, entitled “Hermetically-Covered Photonic Integrated Circuit (PIC) on a Substrate having an Integrated Laser Diode,” filed on Mar. 3, 2023, the disclosure of which is hereby incorporated by reference in its entirety.

### TECHNICAL FIELD

This patent application relates generally to manufacturing and fabrication of optical components, and more specifically, to systems and methods for providing a hermetically-covered photonic integrated circuit on a substrate having an integrated laser diode.

### BACKGROUND

Augmented reality (AR), virtual reality (VR), and mixed reality (MR) are emerging technologies with potential for significant impact(s) on humanity. Various display devices, such as smart glasses, may provide augmented reality, virtual reality, and mixed reality experiences to a user.

In some instances, a display device may include one or more photonic integrated circuits (PICs). A photonic integrated circuit may be used to, among other things, detect, transmit, transport, and/or process optical signals. A photonic integrated circuit may utilize one or more lasers. In particular, the one or more lasers may be implemented via a laser die in conjunction with the photonic integrated circuit.

Often, when integrating a laser die onto a photonic integrated circuit, a number of issues may arise. For example, attachment of the laser die to the photonic integrated circuit may take place via a directed (or “active”) alignment process. In many instances, this process may be inefficient, and may drive up cost of an optical component.

Also, in many instances, a photonic integrated circuit may be fabricated on a transparent substrate to provide a clear optical path and to prevent backwards reflections. Typically, this transparent substrate may exhibit poor thermal properties, and may require a laser to be bonded to a separate, thermally conductive package, and then attached to a photonic integrated circuit wafer. It may be appreciated that this may add cost, and may unnecessarily increase device size (or “bulk”) of an optical component.

### BRIEF DESCRIPTION OF DRAWINGS

Features of the present disclosure are illustrated by way of example and not limited in the following figures, in which like numerals indicate like elements. One skilled in the art will readily recognize from the following that alternative examples of the structures and methods illustrated in the figures can be employed without departing from the principles described herein.

FIG. 1 illustrates a block diagram of an artificial reality system environment including a near-eye display device, according to an example.

FIGS. 2A-2C illustrate various views of a near-eye display device in the form of a head-mounted display (HMD) device, according to examples.

FIG. 3 illustrates a perspective view of a near-eye display device in the form of a pair of glasses, according to an example.

FIG. 4 illustrates a schematic diagram of an optical system in a near-eye display system, according to an example.

FIG. 5 illustrates a block diagram of an optical component including a hermetically-covered photonic integrated circuit, according to an example.

FIG. 6 illustrates a block diagram of an optical component including a hermetically-covered photonic integrated circuit having a fusion bond, according to an example.

FIG. 7 illustrates a block diagram of an optical component including a hermetically-covered photonic integrated circuit having a fusion bonded glass cover with pillars, according to an example.

FIG. 8 illustrates a block diagram of an optical component including a hermetically-covered photonic integrated circuit having a fusion bonded cover with a through-wafer via (TWV) providing electrical connection coupling to the laser die through the base substrate, according to an example.

FIG. 9 illustrates a block diagram of an optical component including a hermetically-covered photonic integrated circuit having an anodic bonded coverer wafer with through-wafer via, according to an example.

FIG. 10 illustrates a block diagram of an optical component including a hermetically-covered photonic integrated circuit having a metal rim bond and a supported window, according to an example.

FIG. 11 illustrates a block diagram of an optical component including a hermetically-covered photonic integrated circuit having a metal rim bond and an unsupported window, according to an example.

FIG. 12 illustrates a block diagram of an optical component including a hermetically-covered photonic integrated circuit having an epoxy bond, according to an example.

### DETAILED DESCRIPTION

For simplicity and illustrative purposes, the present application is described by referring mainly to examples thereof. In the following description, numerous specific details are set forth in order to provide a thorough understanding of the present application. It will be readily apparent, however, that the present application may be practiced without limitation to these specific details. In other instances, some methods and structures readily understood by one of ordinary skill in the art have not been described in detail so as not to unnecessarily obscure the present application. As used herein, the terms “a” and “an” are intended to denote at least one of a particular element, the term “includes” means includes but not limited to, the term “including” means including but not limited to, and the term “based on” means based at least in part on.

Advances in content management and media distribution are causing users to engage with content on or from a variety of content platforms. As used herein, a “user” may include any user of a computing device or digital content delivery mechanism who receives or interacts with delivered content items, which may be visual, non-visual, or a combination thereof. Also, as used herein, “content”, “digital content”, “digital content item” and “content item” may refer to any digital data (e.g., a data file). Examples include, but are not limited to, digital images, digital video files, digital audio files, and/or streaming content. Additionally, the terms “content”, “digital content item,” “content item,” and “digital

item” may refer interchangeably to themselves or to portions thereof. Augmented reality, virtual reality, and mixed reality are emerging technologies with potential for significant impact(s) on humanity. Various digital display devices, such as a smart glasses, may provide augmented reality, virtual reality, and mixed reality experiences to a user.

Typically, smart glasses may include one or more photonic integrated circuits. In some instances, the photonic integrated circuits may be used to, among other things, detect, transmit, transport, and/or process optical signals. A photonic integrated circuit may utilize one or more lasers. In particular, in some examples, the one or more lasers may be implemented via a laser die and may be implemented in conjunction with the photonic integrated circuit.

Often, when integrating a laser die onto a photonic integrated circuit, a number of issues may arise. For example, attachment of the laser die to the photonic integrated circuit may take place via a directed (or “active”) alignment process. In many instances, this process may be inefficient, and may drive up cost of an optical component.

Also, in many instances, a photonic integrated circuit may be fabricated on a transparent substrate to provide a clear optical path and/or to prevent backwards reflections. Typically, the transparent substrate may exhibit poor thermal properties. In some instances, this may require a laser to be bonded to a separate thermally conductive package, and then attached to a photonic integrated circuit wafer. It may be appreciated that this may add cost, and may unnecessarily increase device size (or “bulk”) of an optical component.

In some examples, one or more laser dies may be provided on an optical component, such as a photonic wafer. In some instances, it may be beneficial to provide hermetic covering of the optical component to provide a packaged (or “covered”) protection for its elements (e.g., the one or more laser dies). That is, in some instances, environmental elements may reduce efficiency and lifetime of use of an optical component. However, in such instances, hermetic covering may be utilized with respect to each die (on a “die-by-die level”), which may be less efficient than providing the hermetic covering with respect to the entire wafer (on a “wafer level”).

Systems and methods described herein may provide, among other things, an optical component including a hermetically-covered photonic integrated circuit on a substrate having an integrated laser die. In some examples, as will be described in further detail below, the systems and methods may provide an optical component (e.g., a photonic wafer) that may include a trench with pillars. In some examples, the (e.g., etched) trench with pillars may be utilized to set a height of a laser die relative to a photonic integrated circuit.

In some examples, the systems and methods may enable alignment of a laser die with respect to an input of a photonic integrated circuit. In particular, in some examples, a vertical height of a laser relative to a photonic integrated circuit input may be set (or predetermined), thereby reducing alignment requirements to a single degree of freedom (e.g., that which is in the plane of the PIC and transverse to the optical axis of the input waveguide).Moreover, by reducing an alignment process to a single degree of freedom, a computer vision alignment system may be implemented during fabrication, which may be much more efficient and cost-effective.

In some examples, the systems and methods may provide thermal conduction away from a laser die in order to prevent overheating. That is, in some examples, by fabricating the photonic circuit on a silicon wafer, and then etching a window through the wafer only over the optically emissive area, the systems and methods may provide enhanced thermal conductivity for a laser die.

Also, in some examples, the systems and methods described may provide hermetic covering to protect elements of an optical component (e.g., a photonic wafer) from environmental elements that may reduce efficiency and lifetime of use of the optical component. In some examples, by implementing a wafer glass covering (or “lid”) that may entirely cover the optical component, a hermetic covering of the elements (e.g., one or more laser dies) of the optical component may be provided at a “wafer level.” As a result, a need for separate packaging for each element may be eliminated, thereby providing reduction in a size profile for the optical component and additional cost savings as well.

The systems and methods described herein may provide various additional benefits. In some examples, the systems and methods may enable processes that may be more fabrication-friendly and provide efficient packaging. Moreover, in some examples and as described further below, the systems and methods may provide a window that may enable a removal of light emitted in the “wrong” direction. In particular, in some examples, the systems and methods may provide one or more windows that may enable compatibility with a photonic integrated circuit. Furthermore, the systems and methods may enable use of the photonic integrated circuit as an illumination source for a liquid crystal on silicon (LCOS) display engine, while implementing a reflective design and without a need for a polarized beam splitter.

In some examples, the systems and methods may enable through-wafer via techniques that may be offset from a laser pocket location, in which the through-wafer via arrangement may not need to be airtight. In addition, in some examples, the systems and methods may enable integration of a laser driver circuit as part of complementary metal oxide semiconductor (CMOS) backplane.

In some examples, the systems and methods may include an apparatus, including a housing layer including a waveguide, the waveguide including a photonic integrated circuit, a laser die (or integrated laser diode) to implement one or more lasers in conjunction with the photonic integrated circuit, a cover wafer attached to the housing layer, the cover wafer to provide hermetic covering the photonic integrated circuit and the laser die, and a base substrate attached to the laser die and the housing layer, the base substrate comprising a through-wafer via element coupled to the laser die to provide electrical coupling for the laser die. In some examples, the cover wafer includes a pocket to house the laser die, in which the cover wafer may be attached to the housing layer via a transparent epoxy layer, and/or wherein the cover wafer may be attached to the housing layer via a bonding oxide layer. In some examples, the cover wafer may be attached to the housing layer via a doped oxide layer, the cover wafer may be attached to the housing layer via a metal bonding layer, and/or the base substrate further includes an emission window.

In some examples, the systems and methods may include an apparatus, including a housing layer including a waveguide, the waveguide including a photonic integrated circuit, a laser die (or integrated laser diode) to implement one or more lasers in conjunction with the photonic integrated circuit, a cover wafer attached to the housing layer, the cover wafer to provide hermetic covering the photonic integrated circuit and the laser die, a base substrate attached to the laser die and the housing layer, the base substrate including an emission window adjacent to the housing layer, and a metal connection strip to electrically couple the laser die. In some examples, one or more pillars located in a trench area of the base substrate to set a height of the laser die relative to the photonic integrated circuit, the cover wafer includes a pocket to house the laser die, and/or the laser die includes a laser cavity. In some examples, a silicon dioxide (SiO₂) cladding element on top of the base substrate, the metal connection strip may be provided on top of the silicon dioxide cladding element and on top of the base substrate, and/or the cover wafer may be attached to the housing layer and the silicon dioxide cladding element via a bonding oxide layer.

In some examples, the systems and methods may include an apparatus, including a housing layer including a waveguide, the waveguide including a photonic integrated circuit, a cover wafer attached to the housing layer, the cover wafer to provide hermetic covering the photonic integrated circuit and a laser die (or integrated laser diode), a base substrate attached to the laser die and the housing layer, the base substrate including an emission window adjacent to the housing layer, and a metal connection element coupled to the laser die. In some examples, the cover wafer includes a pocket to house the laser die, in which the cover wafer may be attached to the housing layer via a bonding oxide layer, one or more pillars located in a trench area of the base substrate to set a height of the laser die relative to the photonic integrated circuit, and/or the metal connection element may be provided in the trench area of the base substrate and adjacent to the one or more pillars.

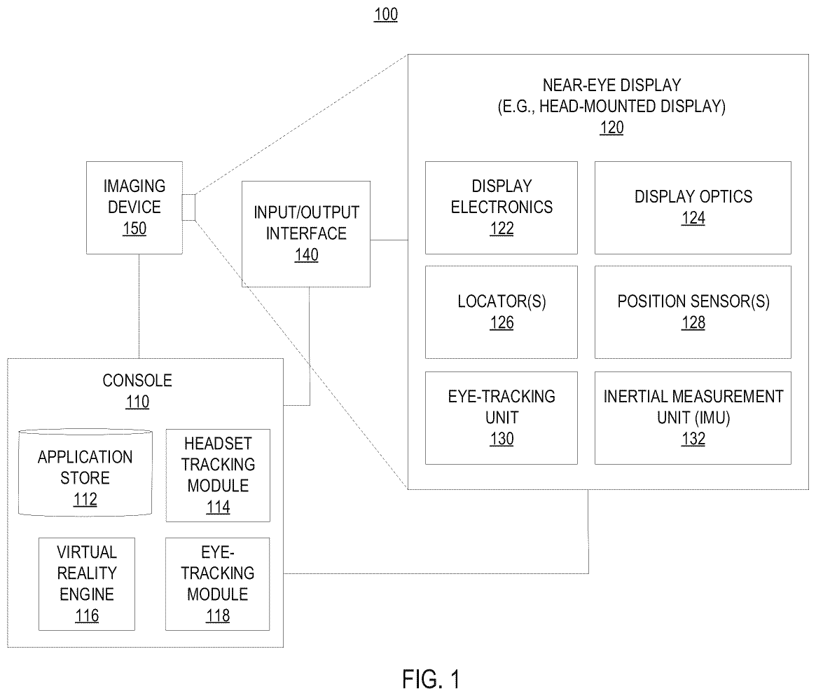

FIG. 1 illustrates a block diagram of an artificial reality system environment 100 including a near-eye display device, according to an example. As used herein, a “near-eye display device” may refer to a device (e.g., an optical device) that may be in close proximity to a user's eye. As used herein, “artificial reality” may refer to aspects of, among other things, a “metaverse” or an environment of real and virtual elements and may include use of technologies associated with virtual reality, augmented reality, and/or mixed reality. As used herein a “user” may refer to a user or wearer of a “near-eye display device.”

As shown in FIG. 1, the artificial reality system environment 100 may include a near-eye display device 120, an optional external imaging device 150, and an optional input/output interface 140, each of which may be coupled to a console 110. The console 110 may be optional in some instances as the functions of the console 110 may be integrated into the near-eye display device 120. In some examples, the near-eye display device 120 may be a head-mounted display that presents content to a user.

In some instances, for a near-eye display device, it may generally be desirable to expand an eye box, reduce display haze, improve image quality (e.g., resolution and contrast), reduce physical size, increase power efficiency, and increase or expand field of view (FOV). As used herein, “field of view” (FOV) may refer to an angular range of an image as seen by a user, which is typically measured in degrees as observed by one eye (for a monocular head-mounted display) or both eyes (for binocular head-mounted displays (HMDs)). Also, as used herein, an “eye box” may be a two-dimensional box that may be positioned in front of the user's eye from which a displayed image from an image source may be viewed.

In some examples, in a near-eye display device, light from a surrounding environment may traverse a “see-through” region of a waveguide display (e.g., a transparent substrate) to reach a user's eyes. For example, in a near-eye display device, light of projected images may be coupled into a transparent substrate of a waveguide, propagate within the waveguide, and be coupled or directed out of the waveguide at one or more locations to replicate exit pupils and expand the eye box.

In some examples, the near-eye display device 120 may include one or more rigid bodies, which may be rigidly or non-rigidly coupled to each other. In some examples, a rigid coupling between rigid bodies may cause the coupled rigid bodies to act as a single rigid entity, while in other examples, a non-rigid coupling between rigid bodies may allow the rigid bodies to move relative to each other.

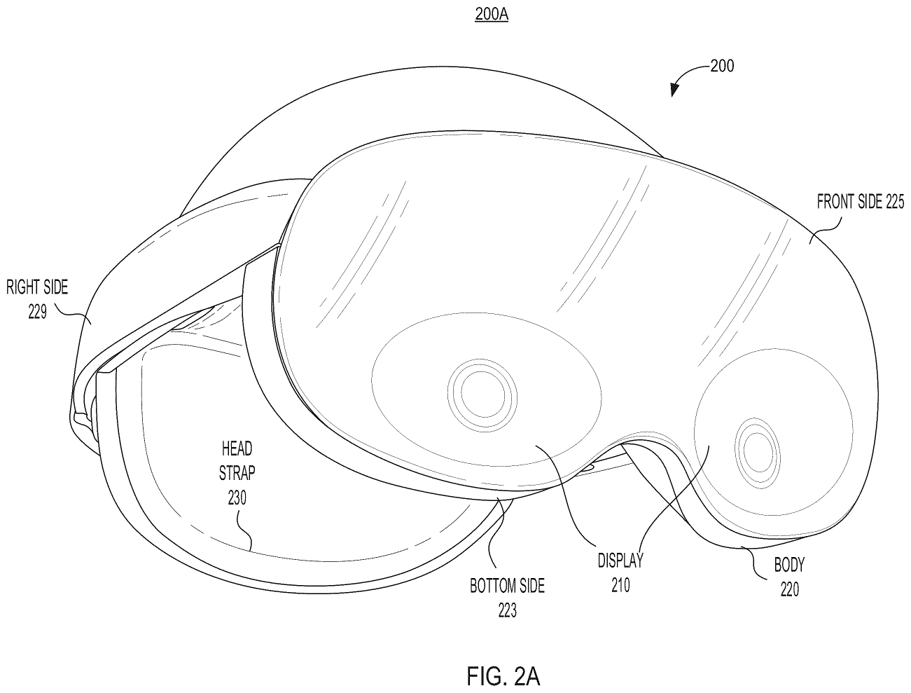

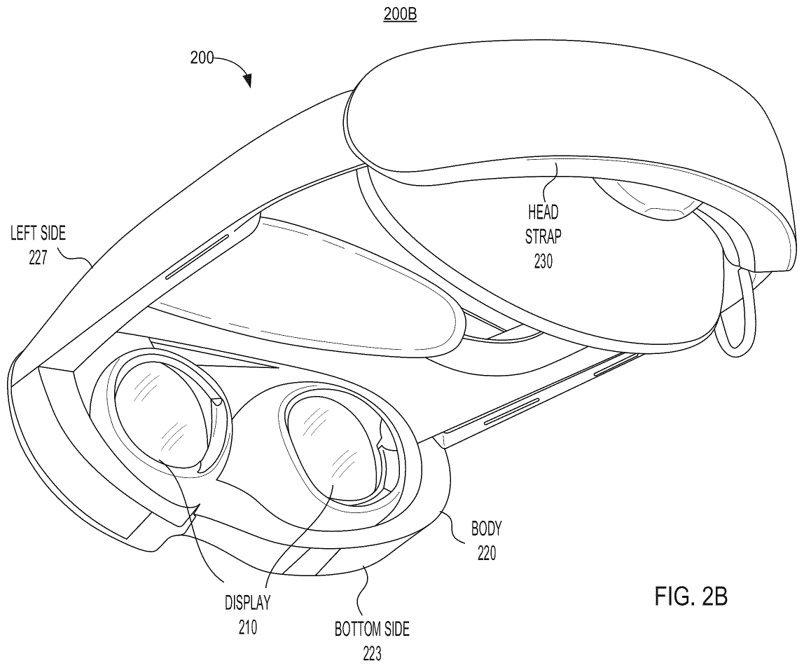

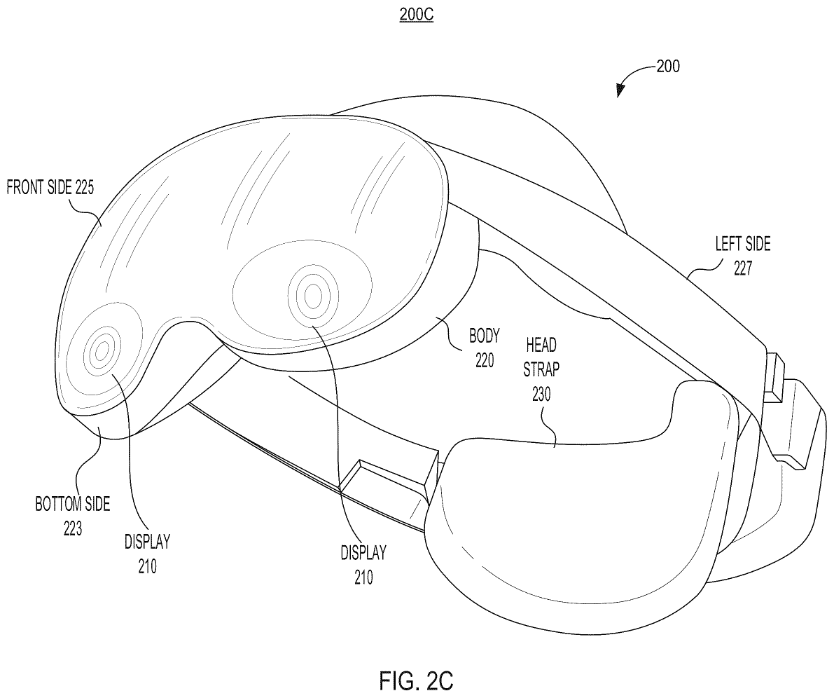

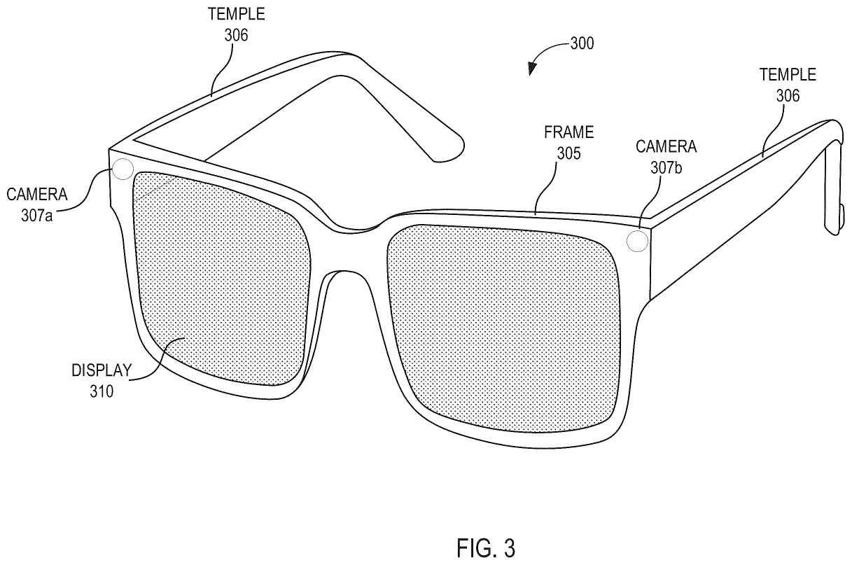

In some examples, the near-eye display device 120 may be implemented in any suitable form-factor, including a head-mounted display, a pair of glasses, or other similar wearable eyewear or device. Examples of the near-eye display device 120 are further described below with respect to FIGS. 2 and 3. Additionally, in some examples, the functionality described herein may be used in a head-mounted display or headset that may combine images of an environment external to the near-eye display device 120 and artificial reality content (e.g., computer-generated images). Therefore, in some examples, the near-eye display device 120 may augment images of a physical, real-world environment external to the near-eye display device 120 with generated and/or overlaid digital content (e.g., images, video, sound, etc.) to present an augmented reality to a user.

In some examples, the near-eye display device 120 may include any number of display electronics 122, display optics 124, and an eye tracking unit 130. In some examples, the near-eye display device 120 may also include one or more locators 126, one or more position sensors 128, and an inertial measurement unit (IMU) 132. In some examples, the near-eye display device 120 may omit any of the eye tracking unit 130, the one or more locators 126, the one or more position sensors 128, and the inertial measurement unit 132, or may include additional elements.

In some examples, the display electronics 122 may display or facilitate the display of images to the user according to data received from, for example, the optional console 110. In some examples, the display electronics 122 may include one or more display panels. In some examples, the display electronics 122 may include any number of pixels to emit light of a predominant color such as red, green, blue, white, or yellow. In some examples, the display electronics 122 may display a three-dimensional (3D) image, e.g., using stereoscopic effects produced by two-dimensional panels, to create a subjective perception of image depth.

In some examples, the near-eye display device 120 may include a projector (not shown), which may form an image in angular domain for direct observation by a viewer's eye through a pupil. The projector may employ a controllable light source (e.g., a laser source) and a micro-electromechanical system (MEMS) beam scanner to create a light field from, for example, a collimated light beam. In some examples, the same projector or a different projector may be used to project a fringe pattern on the eye, which may be captured by a camera and analyzed (e.g., by the eye tracking unit 130) to determine a position of the eye (the pupil), a gaze, etc.

In some examples, the display optics 124 may display image content optically (e.g., using optical waveguides and/or couplers) or magnify image light received from the display electronics 122, correct optical errors associated with the image light, and/or present the corrected image light to a user of the near-eye display device 120. In some examples, the display optics 124 may include a single optical element or any number of combinations of various optical elements as well as mechanical couplings to maintain relative spacing and orientation of the optical elements in the combination. In some examples, one or more optical elements in the display optics 124 may have an optical coating, such as an anti-reflective coating, a reflective coating, a filtering coating, and/or a combination of different optical coatings.

In some examples, the display optics 124 may also be designed to correct one or more types of optical errors, such as two-dimensional optical errors, three-dimensional optical errors, or any combination thereof. Examples of two-dimensional errors may include barrel distortion, pincushion distortion, longitudinal chromatic aberration, and/or transverse chromatic aberration. Examples of three-dimensional errors may include spherical aberration, chromatic aberration field curvature, and astigmatism.

In some examples, the one or more locators 126 may be objects located in specific positions relative to one another and relative to a reference point on the near-eye display device 120. In some examples, the optional console 110 may identify the one or more locators 126 in images captured by the optional external imaging device 150 to determine the artificial reality headset's position, orientation, or both. The one or more locators 126 may each be a light-emitting diode (LED), a corner cube reflector, a reflective marker, a type of light source that contrasts with an environment in which the near-eye display device 120 operates, or any combination thereof.

In some examples, the external imaging device 150 may include one or more cameras, one or more video cameras, any other device capable of capturing images including the one or more locators 126, or any combination thereof. The optional external imaging device 150 may be configured to detect light emitted or reflected from the one or more locators 126 in a field of view of the optional external imaging device 150.

In some examples, the one or more position sensors 128 may generate one or more measurement signals in response to motion of the near-eye display device 120. Examples of the one or more position sensors 128 may include any number of accelerometers, gyroscopes, magnetometers, and/or other motion-detecting or error-correcting sensors, or any combination thereof.

In some examples, the inertial measurement unit 132 may be an electronic device that generates fast calibration data based on measurement signals received from the one or more position sensors 128. The one or more position sensors 128 may be located external to the inertial measurement unit 132, internal to the inertial measurement unit 132, or any combination thereof. Based on the one or more measurement signals from the one or more position sensors 128, the inertial measurement unit 132 may generate fast calibration data indicating an estimated position of the near-eye display device 120 that may be relative to an initial position of the near-eye display device 120. For example, the inertial measurement unit 132 may integrate measurement signals received from accelerometers over time to estimate a velocity vector and integrate the velocity vector over time to determine an estimated position of a reference point on the near-eye display device 120. Alternatively, the inertial measurement unit 132 may provide the sampled measurement signals to the optional console 110, which may determine the fast calibration data.

The eye tracking unit 130 may include one or more eye tracking systems. As used herein, “eye tracking” may refer to determining an eye's position or relative position, including orientation, location, and/or gaze of a user's eye. In some examples, an eye tracking system may include an imaging system that captures one or more images of an eye and may optionally include a light emitter, which may generate light (e.g., a fringe pattern) that is directed to an eye such that light reflected by the eye may be captured by the imaging system (e.g., a camera). In other examples, the eye tracking unit 130 may capture reflected radio waves emitted by a miniature radar unit. These data associated with the eye may be used to determine or predict eye position, orientation, movement, location, and/or gaze.

In some examples, the near-eye display device 120 may use the orientation of the eye to introduce depth cues (e.g., blur image outside of the user's main line of sight), collect heuristics on the user interaction in the virtual reality (VR) media (e.g., time spent on any particular subject, object, or frame as a function of exposed stimuli), some other functions that are based in part on the orientation of at least one of the user's eyes, or any combination thereof. In some examples, because the orientation may be determined for both eyes of the user, the eye tracking unit 130 may be able to determine where the user is looking or predict any user patterns, etc.

In some examples, the input/output interface 140 may be a device that allows a user to send action requests to the optional console 110. As used herein, an “action request” may be a request to perform a particular action. For example, an action request may be to start or to end an application or to perform a particular action within the application. The input/output interface 140 may include one or more input devices. Example input devices may include a keyboard, a mouse, a game controller, a glove, a button, a touch screen, or any other suitable device for receiving action requests and communicating the received action requests to the optional console 110. In some examples, an action request received by the input/output interface 140 may be communicated to the optional console 110, which may perform an action corresponding to the requested action.

In some examples, the optional console 110 may provide content to the near-eye display device 120 for presentation to the user in accordance with information received from one or more of external imaging device 150, the near-eye display device 120, and the input/output interface 140. For example, in the example shown in FIG. 1, the optional console 110 may include an application store 112, a headset tracking module 114, a virtual reality engine 116, and an eye tracking module 118. Some examples of the optional console 110 may include different or additional modules than those described in conjunction with FIG. 1. Functions further described below may be distributed among components of the optional console 110 in a different manner than is described here.

In some examples, the optional console 110 may include a processor and a non-transitory computer-readable storage medium storing instructions executable by the processor. The processor may include multiple processing units executing instructions in parallel. The non-transitory computer-readable storage medium may be any memory, such as a hard disk drive, a removable memory, or a solid-state drive (e.g., flash memory or dynamic random access memory (DRAM)). In some examples, the modules of the optional console 110 described in conjunction with FIG. 1 may be encoded as instructions in the non-transitory computer-readable storage medium that, when executed by the processor, cause the processor to perform the functions further described below. It should be appreciated that the optional console 110 may or may not be needed or the optional console 110 may be integrated with or separate from the near-eye display device 120.

In some examples, the application store 112 may store one or more applications for execution by the optional console 110. An application may include a group of instructions that, when executed by a processor, generates content for presentation to the user. Examples of the applications may include gaming applications, conferencing applications, video playback application, or other suitable applications.

In some examples, the headset tracking module 114 may track movements of the near-eye display device 120 using slow calibration information from the external imaging device 150. For example, the headset tracking module 114 may determine positions of a reference point of the near-eye display device 120 using observed locators from the slow calibration information and a model of the near-eye display device 120. Additionally, in some examples, the headset tracking module 114 may use portions of the fast calibration information, the slow calibration information, or any combination thereof, to predict a future location of the near-eye display device 120. In some examples, the headset tracking module 114 may provide the estimated or predicted future position of the near-eye display device 120 to the virtual reality engine 116.

In some examples, the virtual reality engine 116 may execute applications within the artificial reality system environment 100 and receive position information of the near-eye display device 120, acceleration information of the near-eye display device 120, velocity information of the near-eye display device 120, predicted future positions of the near-eye display device 120, or any combination thereof from the headset tracking module 114. In some examples, the virtual reality engine 116 may also receive estimated eye position and orientation information from the eye tracking module 118. Based on the received information, the virtual reality engine 116 may determine content to provide to the near-eye display device 120 for presentation to the user.

In some examples, the eye tracking module 118, which may be implemented as a processor, may receive eye tracking data from the eye tracking unit 130 and determine the position of the user's eye based on the eye tracking data. In some examples, the position of the eye may include an eye's orientation, location, or both relative to the near-eye display device 120 or any element thereof. So, in these examples, because the eye's axes of rotation change as a function of the eye's location in its socket, determining the eye's location in its socket may allow the eye tracking module 118 to more accurately determine the eye's orientation.

In some examples, a location of a projector of a display system may be adjusted to enable any number of design modifications. For example, in some instances, a projector may be located in front of a viewer's eye (e.g., “front-mounted”placement). In a front-mounted placement, in some examples, a projector of a display system may be located away from a user's eyes (e.g., “world-side”). In some examples, a head-mounted display device may utilize a front-mounted placement to propagate light towards a user's eye(s) to project an image.

FIGS. 2A-2C illustrate various views of a near-eye display device in the form of a head-mounted display device 200, according to examples. In some examples, the head-mounted device (HMD) device 200 may be a part of a virtual reality system, an augmented reality system, a mixed reality system, another system that uses displays or wearables, or any combination thereof. As shown in diagram 200A of FIG. 2A, the head-mounted display device 200 may include a body 220 and a head strap 230. The front perspective view of the head-mounted display device 200 further shows a bottom side 223, a front side 225, and a right side 229 of the body 220. In some examples, the head strap 230 may have an adjustable or extendible length. In particular, in some examples, there may be a sufficient space between the body 220 and the head strap 230 of the head-mounted display device 200 for allowing a user to mount the head-mounted display device 200 onto the user's head. For example, the length of the head strap 230 may be adjustable to accommodate a range of user head sizes. In some examples, the head-mounted display device 200 may include additional, fewer, and/or different components such as a display 210 to present a wearer augmented reality/virtual reality content and a camera to capture images or videos of the wearer's environment.

As shown in the bottom perspective view of diagram 200B of FIG. 2B, the display 210 may include one or more display assemblies and present, to a user (wearer), media or other digital content including virtual and/or augmented views of a physical, real-world environment with computer-generated elements. Examples of the media or digital content presented by the head-mounted display device 200 may include images (e.g., two-dimensional (2D) or three-dimensional (3D) images), videos (e.g., 2D or 3D videos), audio, or any combination thereof. In some examples, the user may interact with the presented images or videos through eye tracking sensors enclosed in the body 220 of the head-mounted display device 200. The eye tracking sensors may also be used to adjust and improve quality of the presented content.

In some examples, the head-mounted display device 200 may include a fringe-projection profilometry (FPP) projector and the camera or the eye tracking sensors may include a dual readout sensor. The projector may transmit a frequency signal pattern and a zero-frequency signal pattern onto an object's (e.g., eye in case of eye tracking) surface. The projector may also transmit two periodic phase-shifted frequency signal patterns onto the object's surface, where the two phase-shifted frequency signal patterns may be phase-shifted by 180 degrees. The dual readout sensor may capture reflections of both transmitted patterns (frequency and zero frequency or phase-shifted frequency signal patterns), and a direct component (DC) signal may be removed through subtraction or cancellation. In both examples, the derived signal may be used to generate a wrapped phase map through Fourier transform profilometry (FTP). The resulting wrapped phase map may be unwrapped, for example, using a depth-calibrated unwrapped phase map. A three-dimensional reconstruction of the object's surface may be generated by converting phase from the unwrapped phase map to three-dimensional coordinates.

In some examples, the head-mounted display device 200 may include various sensors (not shown), such as depth sensors, motion sensors, position sensors, and/or eye tracking sensors. Some of these sensors may use any number of structured or unstructured light patterns for sensing purposes. In some examples, the head-mounted display device 200 may include an input/output interface for communicating with a console communicatively coupled to the head-mounted display device 200 through wired or wireless means. In some examples, the head-mounted display device 200 may include a virtual reality engine (not shown) that may execute applications within the head-mounted display device 200 and receive depth information, position information, acceleration information, velocity information, predicted future positions, or any combination thereof of the head-mounted display device 200 from the various sensors.

In some examples, as provided in the perspective view of diagram 200C of FIG. 2C, information received by the virtual reality engine may be used for producing a signal (e.g., display instructions) to the display 210. In some examples, the head-mounted display device 200 may include locators (not shown), which may be located in fixed positions on the body 220 of the head-mounted display device 200 relative to one another and relative to a reference point. Each of the locators may emit light that is detectable by an external imaging device. This may be useful for the purposes of head tracking or other movement/orientation. It should be appreciated that other elements or components may also be used in addition or in lieu of such locators.

FIG. 3 is a perspective view of a near-eye display device 300 in the form of a pair of glasses (or other similar eyewear), according to an example. In some examples, the near-eye display device 300 may be a specific example of near-eye display device 120 of FIG. 1 and may be configured to operate as a virtual reality display, an augmented reality display, and/or a mixed reality (MR) display.

In some examples, the near-eye display device 300 may include a frame 305 and a display 310. In some examples, the display 310 may be configured to present media or other content to a user. In some examples, the display 310 may include display electronics and/or display optics, similar to components described with respect to FIGS. 1-2. For example, as described above with respect to the near-eye display device 120 of FIG. 1, the display 310 may include a liquid crystal display (LCD) display panel, a light-emitting diode (LED) display panel, or an optical display panel (e.g., a waveguide display assembly). In some examples, the display 310 may also include any number of optical components, such as waveguides, gratings, lenses, mirrors, etc. In other examples, the display 210 may include a projector, or in place of the display 310 the near-eye display device 300 may include a projector.

In some examples, the near-eye display device 300 may further include various sensors on or within a frame 305. In some examples, the various sensors may include any number of depth sensors, motion sensors, position sensors, inertial sensors, and/or ambient light sensors, as shown. In some examples, the various sensors may include any number of image sensors configured to generate image data representing different fields of views in one or more different directions. In some examples, the various sensors may be used as input devices to control or influence the displayed content of the near-eye display device, and/or to provide an interactive virtual reality, augmented reality, and/or mixed reality experience to a user of the near-eye display device 300. In some examples, the various sensors may also be used for stereoscopic imaging or other similar applications.

In some examples, the near-eye display device 300 may further include one or more illuminators to project light into a physical environment. The projected light may be associated with different frequency bands (e.g., visible light, infra-red light, ultraviolet light, etc.), and may serve various purposes. In some examples, the one or more illuminator(s) may be used as locators, such as the one or more locators 126 described above with respect to FIGS. 1-2.

In some examples, the near-eye display device 300 may also include a plurality of cameras 307a-307b or other image capture unit or units. The plurality of cameras 307a-307b, for instance, may capture images of the physical environment in the field of view. In some examples, the plurality of cameras 307a-307b may be capable of simultaneous, stereoscopic video capture, where a first camera 307a of the plurality of cameras 307a-307b may be located near a first hinge of the pair of smart glasses and a second camera 307b of the plurality of cameras 307a-307b may be located near a second hinge of the pair of smart glasses. In some instances, the captured images may be processed, for example, by a virtual reality engine (e.g., the virtual reality engine 116 of FIG. 1) to add virtual objects to the captured images or modify physical objects in the captured images, and the processed images may be displayed to the user by the display 310 for augmented reality and/or mixed reality applications. The near-eye display device 300 may also include an eye tracking camera.

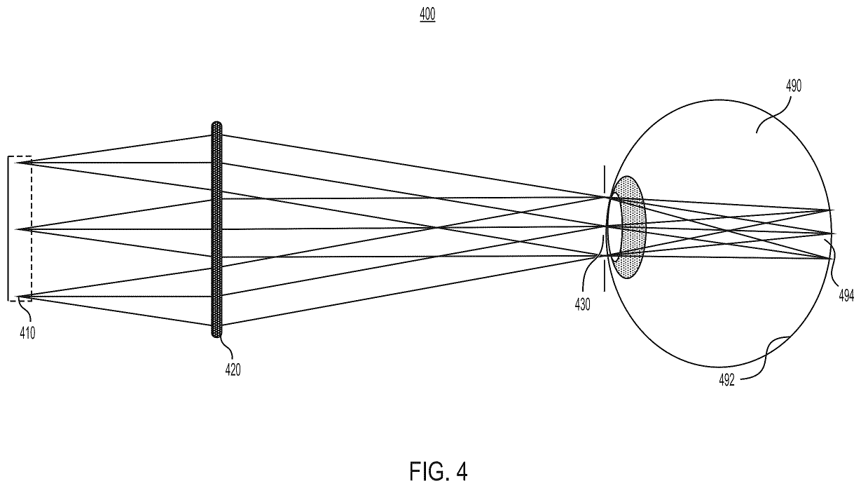

FIG. 4 illustrates a schematic diagram of an optical system 400 in a near-eye display system, according to an example. In some examples, the optical system 400 may include an image source 410 and any number of projector optics 420 (which may include waveguides having gratings as discussed herein). In the example shown in FIG. 4, the image source 410 may be positioned in front of the projector optics 420 and may project light toward the projector optics 420. In some examples, the image source 410 may be located outside of the field of view of a user's eye 490. In this case, the projector optics 420 may include one or more reflectors, refractors, or directional couplers that may deflect light from the image source 410 that is outside of the field of view of the user's eye 490 to make the image source 410 appear to be in front of the user's eye 490. Light from an area (e.g., a pixel or a light emitting device) on the image source 410 may be collimated and directed to an exit pupil 430 by the projector optics 420. Thus, objects at different spatial locations on the image source 410 may appear to be objects far away from the user's eye 490 in different viewing angles (e.g., fields of view). The collimated light from different viewing angles may then be focused by the lens of the user's eye 490 onto different locations on retina 492 of the user's eye 490. For example, at least some portions of the light may be focused on a fovea 494 on the retina 492. Collimated light rays from an area on the image source 410 and incident on the user's eye 490 from a same direction may be focused onto a same location on the retina 492. As such, a single image of the image source 410 may be formed on the retina 492.

In some instances, a user experience of using an artificial reality system may depend on several characteristics of the optical system, including field of view, image quality (e.g., angular resolution), size of the eyebox (to accommodate for eye and head movements), and brightness of the light (or contrast) within the eyebox. Also, in some examples, to create a fully immersive visual environment, a large field of view may be desirable because a large field of view (e.g., greater than about 60°) may provide a sense of “being in” an image, rather than merely viewing the image. In some instances, smaller fields of view may also preclude some important visual information. For example, a head-mounted display system with a small field of view may use a gesture interface, but users may not readily see their hands in the small field of view to be sure that they are using the correct motions or movements. On the other hand, wider fields of view may require larger displays or optical systems, which may influence the size, weight, cost, and/or comfort of the head-mounted display itself.

In some examples, a waveguide may be utilized to couple light into and/or out of a display system. In particular, in some examples and as described further below, light of projected images may be coupled into or out of the waveguide using any number of reflective or diffractive optical elements, such as gratings. For example, as described further below, one or more volume Bragg gratings (VBGs) may be utilized in a waveguide-based, back-mounted display system (e.g., a pair of glasses or similar eyewear).

In some examples, one or more volume Bragg gratings (VBGs) (or two portions of a same grating) may be used to diffract display light from a projector to a user's eye. Furthermore, in some examples, the one or more volume Bragg gratings (VBGs) may also help compensate for any dispersion of display light caused by each other to reduce the overall dispersion in a waveguide-based display system.

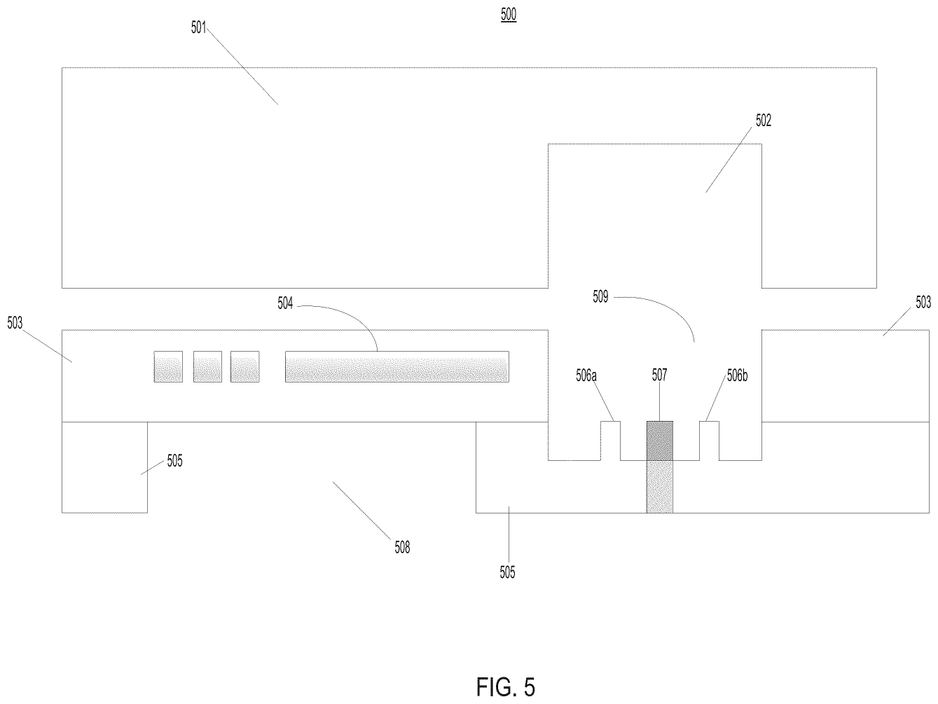

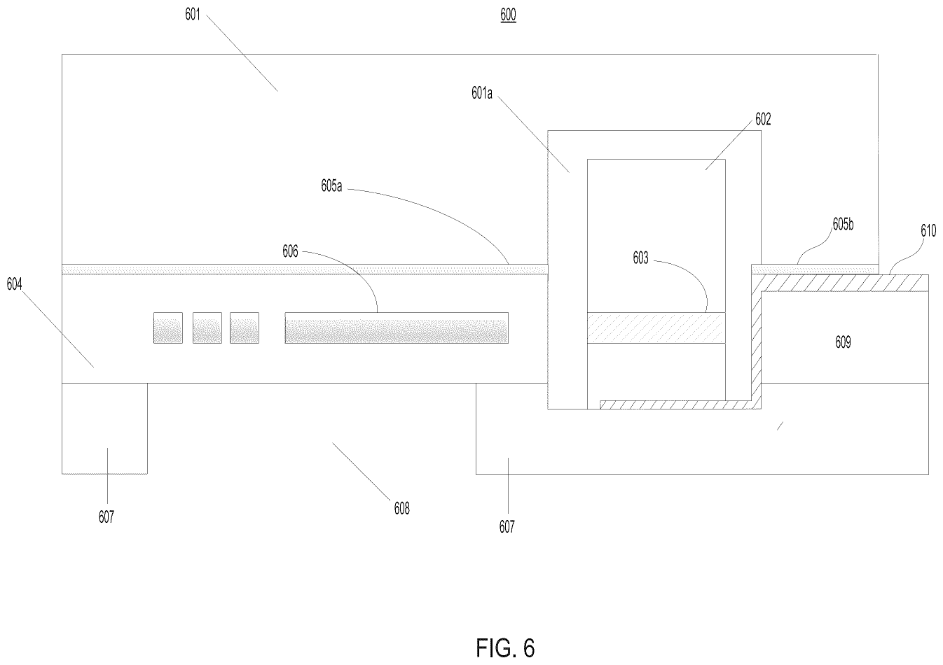

Reference is now made to FIGS. 5-12. It should be appreciated that the examples illustrated in FIGS. 5-12, as described further below, may provide various ways of attaching a laser and providing electrical contact (or providing electricity) to a laser die (e.g., via a metal connection). In addition, the examples illustrated in FIGS. 5-12 may provide various ways of attaching a cover wafer to a photonic integrated circuit. It may further be appreciated that although an element (e.g., the one or more pillars 506a, 506b) shown in a first example (e.g., the example illustrated in FIG. 5) may not be shown in a second example (e.g., the example illustrated in FIG. 6), this does not mean that the element may not be provided in another configuration similar to the second example.

In some examples, and as will be discussed further below, the examples illustrated in FIGS. 5-12 may enable alignment of a controllable light source a near-eye display device (e.g., the near-eye display device 120). So, in some examples, a vertical height of a laser relative to a photonic integrated circuit input (e.g., included in a near-eye display device) may be set (or predetermined), thereby reducing alignment requirements to a single degree of freedom and enabling implementation of a computer vision alignment system may be implemented during fabrication, which may be much more efficient and cost-effective. Also, in some examples, the examples illustrated in FIGS. 5-12 may provide thermal conduction away from a laser die in order to prevent overheating of the near-eye display device. Furthermore, in some examples, hermetic covering to protect elements of an optical component (e.g., a photonic wafer in a near-eye display device) from environmental elements may reduce efficiency and lifetime of use of the optical component.

FIG. 5 illustrates a block diagram of an optical component 500 having a hermetically-covered photonic integrated circuit, according to an example. In some examples, the optical component 500 may include a cover wafer (or “hermetic cover wafer”) 501 having a pocket 502 (or “recess 502”) to, among other things, house a laser die. In some examples, the cover wafer 501 may be included of glass, and may be utilized to (among other things) operate as a “lid” that may cover an underlying substrate and prevent introduction of environmental elements (e.g., air, moisture, etc.).

In some examples, the optical component 500 may further include a housing layer 503 provided on top of a base substrate (or “base wafer”) 505. In some examples, the housing layer 503 may be composed of a transparent material, and in other examples, the housing layer 503 may be an oxide layer. In some examples, the housing layer 503 may include a photonic integrated circuit 504. In some examples, the cover wafer 501 may be utilized to hermetically cover (or seal) the photonic integrated circuit 504. Also, in some examples, a laser die (not shown) may emit an optical signal to couple into the photonic integrated circuit 504.

In some examples, the base substrate 505 may be composed of silicon, glass, or another transparent material. In some examples, the base substrate 505 may include an (e.g., etched) emission window 508 (e.g., where the base substrate 505 may be composed of silicon), while in other examples, an emission window may not be included (e.g., where the base substrate 505 may be composed of a transparent material). In some examples, the emission window 508 may be transparent (in that it may pass light), and thereby prevent unwanted back reflections, or otherwise allow light to pass through the base substrate.

In some examples, the base substrate 505 may further include one or more pillars 506a, 506b, a metal connection element 507, and a trench area 509. In some examples, the trench area 509 may house the one or more pillars 506a, 506b and the metal connection element 507. Also, in some examples, the one or more pillars 506a, 506b may be utilized to set a height of a laser die (not shown) relative the photonic integrated circuit 504. Moreover, in some examples, the metal connection element 507 may be utilized to provide power or information to a laser die, and bond (or adhere) the laser die to the base substrate.

FIG. 6 illustrates a block diagram of an optical component 600 having a hermetically-covered photonic integrated circuit having a fusion bond, according to an example. In some examples, the optical component 600 may include a cover wafer 601. In some examples, the cover wafer may include a pocket 601a (e.g., similar to the pocket 502 in FIG. 5) to house a laser die. In some examples, the cover wafer 601 may be composed of silicon dioxide (SiO₂).

In some examples, the cover wafer 601 may be attached to a housing layer 604 via an oxide layer 605a. In some examples, the housing layer 604 may include a waveguide. In some examples, the waveguide may include a photonic integrated circuit 606.

In some examples, the housing layer 604 may be provided on top of a base substrate (or “carrier wafer”) 607. In some examples, the base substrate 607 may be composed of silicon. Also, in some examples, the base substrate 607 may include an emission window 608. In some examples, the emission window 608 may be etched, and may be transparent (in that it may pass light).

In some examples, a silicon dioxide cladding element 609 may be provided on top of a base substrate 607, where a metal connection strip 610 may be provided (in part) on top and/or alongside of the silicon dioxide cladding element 609, and may electrically couple with a laser die 602. In some examples, the laser die 602 may be housed in a pocket 601a of the cover wafer 601. In some examples, the laser die 602 may include a laser cavity 603. In some examples, the laser cavity 603 may include arrangement of optical elements (e.g., one or more mirrors) that facilitates resonance for light waves. In some examples, an oxide layer 605b may couple the metal connection strip 610 and the cover wafer 601.

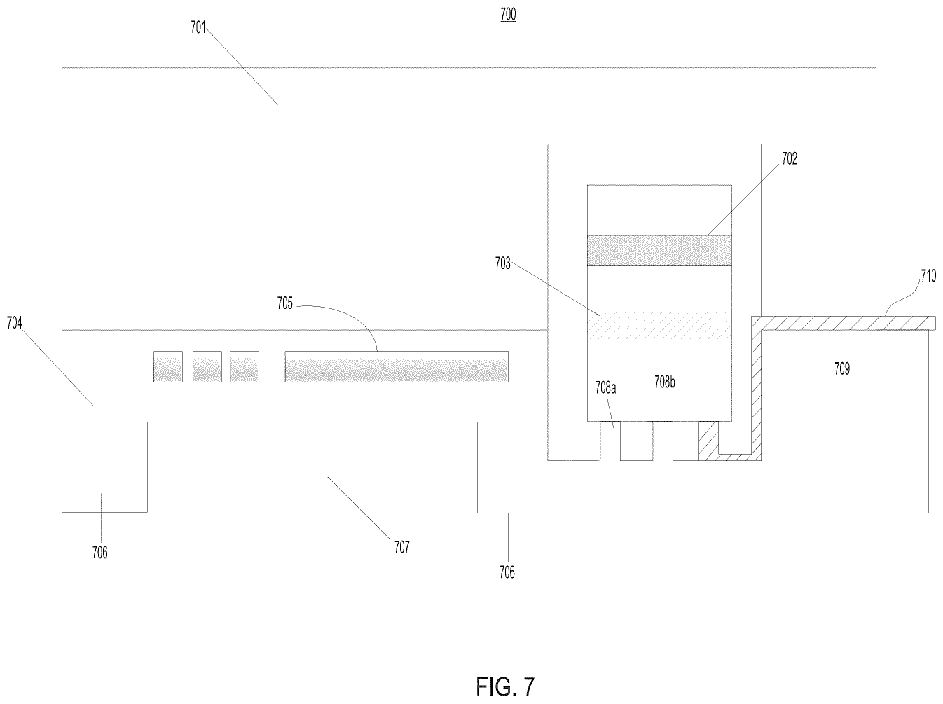

FIG. 7 illustrates a block diagram of an optical component 700 including a hermetically-covered photonic integrated circuit having a fusion bonded cover wafer with pillars, according to an example. In some examples, the optical component 700 may include a cover wafer 701. In some examples, the cover wafer 701 may be composed of silicon dioxide (SiO₂).

In some examples, the cover wafer 701 may be attached to a housing layer 704. In some examples, the housing layer 704 may include a waveguide 705. In some examples, the waveguide 705 may include a photonic integrated circuit.

In some examples, the housing layer 704 may be provided on top of a base substrate (or “carrier wafer”) 706. In some examples, the base substrate 706 may be composed of silicon. Also, in some examples, the base substrate 706 may include an emission window 707 that may be etched.

In some examples, the base substrate 706 may include one or more etched pillars 708a, 708b. Similar to the example illustrated in FIG. 5, in some instances, the one or more pillars 708a, 708b may be utilized to set a height of a laser die (not shown) relative a photonic integrated circuit. In particular, in the example illustrated in FIG. 7, the one or more pillars 708a, 708b may be utilized to set a height of a laser die 702 with respect to a photonic integrated circuit in the waveguide 705. In some examples, the laser die 702 may include a laser cavity 703. In some examples, the laser die 702 may be housed in a pocket (e.g., similar to the pocket 601a) of the cover wafer 701.

In some examples, a silicon dioxide cladding element 709 may be provided on top of the base substrate 706. Also, in some examples, a metal connection strip 710 may be provided on top of the silicon dioxide cladding element 709, and may be used to electrically couple the laser die 702.

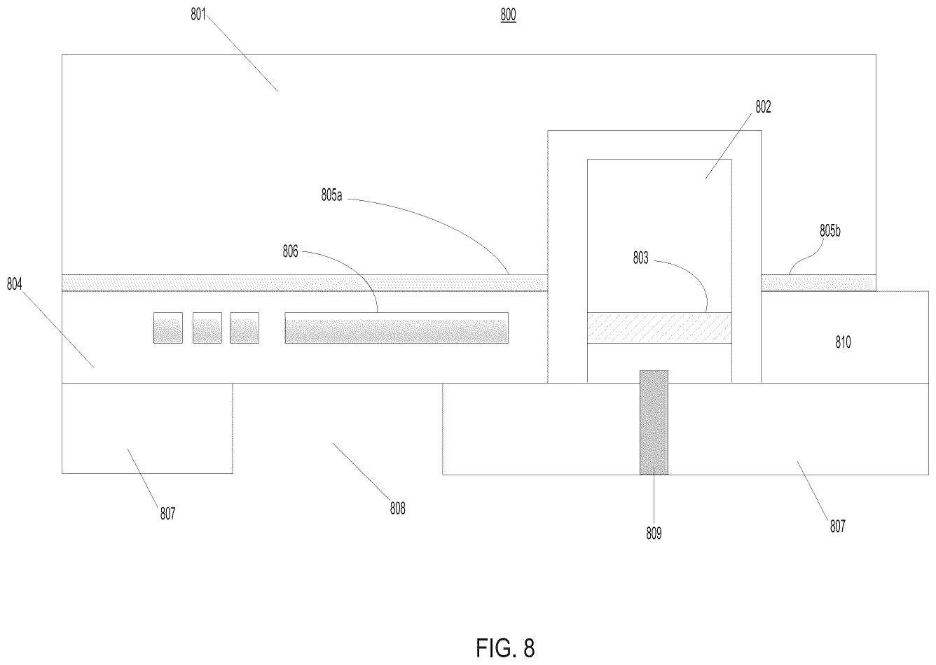

FIG. 8 illustrates a block diagram of an optical component 800 including a hermetically-covered photonic integrated circuit having a fusion bonded cover with a through-wafer via providing electrical coupling to the laser die through the base substrate, according to an example. In some examples, the optical component 800 may include a cover wafer 801. In some examples, the cover wafer 801 may be composed of silicon dioxide (SiO₂).

In some examples, the cover wafer 801 may be attached to a housing layer 804 via an oxide layer 805a (or “bonding oxide layer”). In some examples, the oxide layer 805a may enable fusion bonding. In some examples, the housing layer 804 may include a waveguide, which may include a photonic integrated circuit 806.

In some examples, the housing layer 804 may be provided on top of a base substrate (or “carrier wafer”) 807. Also, in some examples, the base substrate 807 may be composed of silicon, and may include an emission window 808 that may be etched into the base substrate 807.

In some examples, the base substrate 807 may include a through-wafer via element 809 to provide electrical coupling to a laser die 802. That is, in some examples, the through-wafer via element 809 may provide a connection through the base substrate 807, rather than being placed on top of the base substrate 807 (e.g., similar to the one or more etched pillars 708a, 708b in FIG. 7). In some examples, the laser die 802 may include a laser cavity 803. In some examples, the laser die 802 may be housed in a pocket of the cover wafer 801.

It may be appreciated that the through-wafer via element 809 may operate in conjunction with one or more elements illustrated in FIGS. 5-7 and 9-12. In particular, the through-wafer via may work in conjunction with the one or more etched pillars 708a, 708b illustrated in FIG. 7, in which additional (e.g., metal) pillars may be utilized to connect between a trench where a through-wafer via may be end and a bottom of a laser die. In some examples, the additional pillars may provide both a bond that may hold the laser die in place, and may further provide an electrical coupling from a base of the trench to the laser die. In addition, a connection from the base of the trench to a point outside of a hermetic cover (or “hermetic seal”) wafer may either provided by the through-wafer via, or by metal connection that may be provided on a side of the trench and under an oxide layer.

In some examples, a silicon dioxide cladding element 810 may be provided on top of the base substrate 807, and an oxide layer 805b (or “bonding oxide layer”) may couple the silicon dioxide cladding element 810 to the cover wafer 801. In some examples, the oxide layer 805b may enable fusion bonding of the cover wafer to the housing layer.

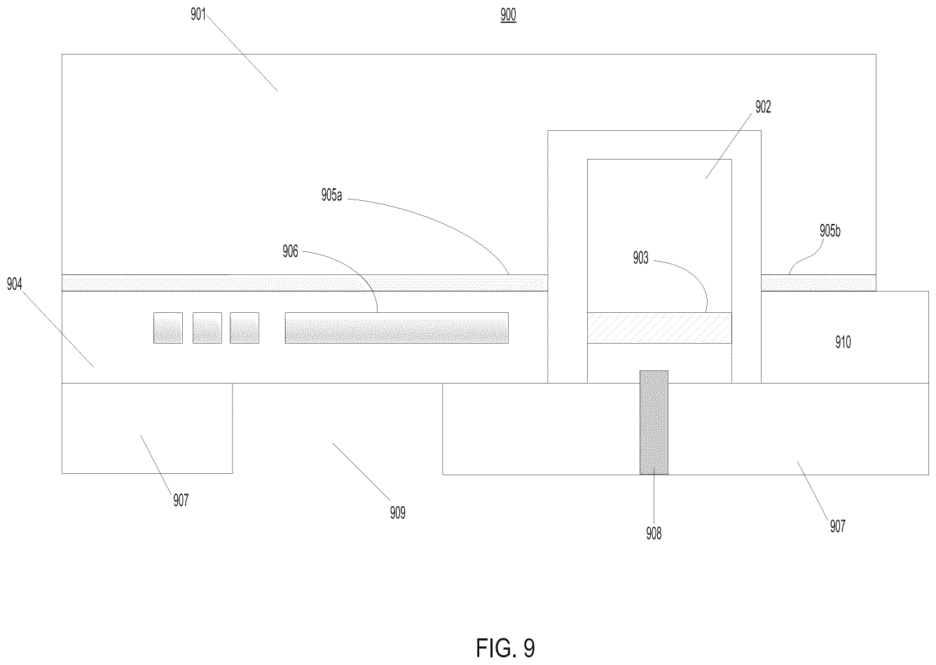

FIG. 9 illustrates a block diagram of an optical component 900 including a hermetically-covered photonic integrated circuit having an anodic bonded coverer wafer with through-wafer via, according to an example. In some examples, the optical component 900 may include a cover wafer 901. In some examples, the cover wafer 901 may be composed of silicon dioxide (SiO₂).

In some examples, the cover wafer 901 may be attached to a housing layer 904 via a doped oxide layer 905a. In some examples, the doped oxide layer 905a may enable anodic bonding. In some examples, the housing layer 904 may include a waveguide 906, which may include a photonic integrated circuit.

In some examples, the housing layer 904 may be provided on top of a base (e.g., silicon) substrate 907. Also, in some examples, the base substrate 907 may include an emission window 909 that may be etched into the base substrate.

In some examples, the base substrate 907 may include a through-wafer via element 908 coupled to a laser die 902. That is, in some examples, the through-wafer via element 908 may provide a connection through a base substrate 907, rather than being placed on top of the base substrate 907 (e.g., similar to the one or more etched pillars 708a, 708b in FIG. 7). In some examples, the laser die 902 may include a laser cavity 903.

In some examples, a silicon dioxide cladding 910 may be provided on top of the base substrate 907, and a doped oxide layer 905b may couple the silicon dioxide cladding 910 to the cover wafer 901. In some examples, the doped oxide layer 905b may enable anodic bonding of the cover wafer 901 the silicon dioxide cladding 910.

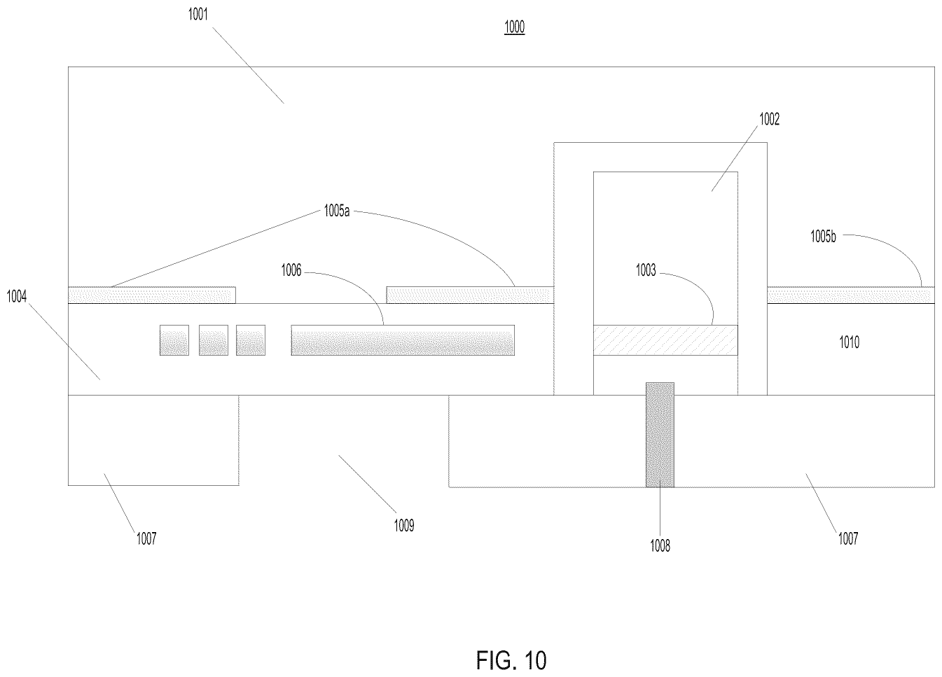

FIG. 10 illustrates a block diagram of an optical component 1000 including a hermetically-covered photonic integrated circuit having a metal rim bond and a supported window, according to an example. In some examples, the optical component 1000 may include a cover wafer 1001. In some examples, the cover wafer 1001 may be composed of silicon dioxide (SiO₂).

In some examples, the cover wafer 1001 may be attached to a housing layer 1004 via a metal bonding layer 1005a. In some examples, the housing layer 1004 may include a waveguide 1006, and the waveguide 1006 may include a photonic integrated circuit. So, while in some examples (e.g., the example illustrated in FIG. 9), the bond between a cover wafer and a housing layer may be a “glass-to-glass” bond, in this example, the bond between the cover wafer 1001 and the housing layer 1004 may be a “metal-to-metal” bond.

In some examples, the housing layer 1004 may be provided on top of the base substrate 1007. Also, in some examples, the base substrate 1007 may include an etched emission window 1009.

In some examples, the base substrate 1007 may include a through-wafer via element 1008 to enable electrical coupling to a laser die 1002. That is, in some examples, the through-wafer via element 1008 may provide a connection through a base substrate 1007, rather than being placed on top of the base substrate 1007 (e.g., similar to the one or more etched pillars 708a, 708b in FIG. 7). In some examples, the laser die 1002 may include a laser cavity 1003.

In some examples, a silicon dioxide cladding element 1010 may be provided on top of the base substrate 1007, and a metal bonding layer 1005b may couple the silicon dioxide cladding element 1010 to the cover wafer 1001.

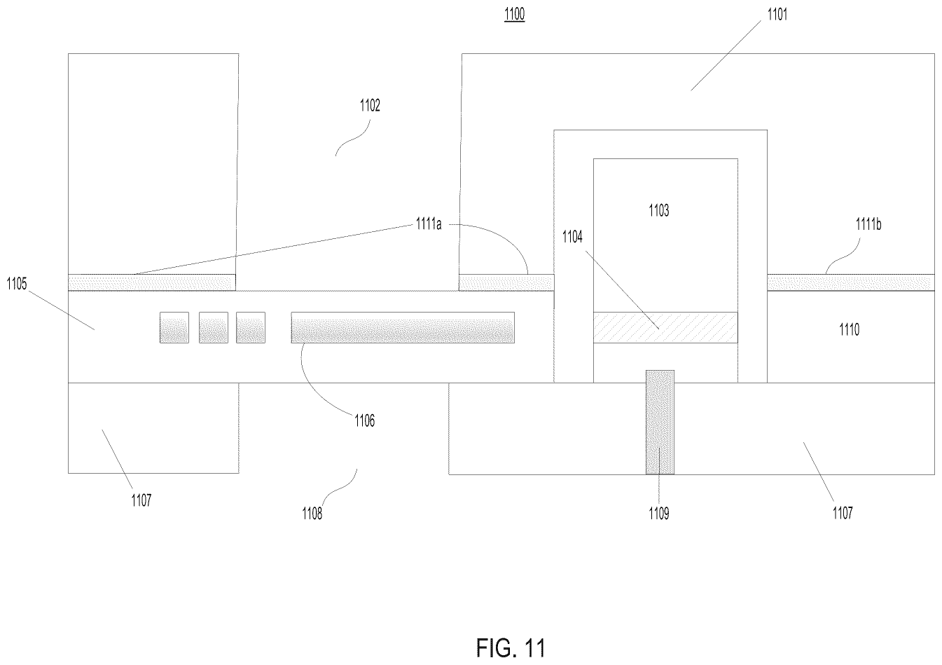

FIG. 11 illustrates a block diagram of an optical component 1100 including a hermetically-covered photonic integrated circuit having a metal rim bond and an unsupported window, according to an example. In some examples, the optical component 1100 may include a cover wafer 1101. In some examples, the cover wafer 1101 may be composed of silicon dioxide (SiO₂).

In some examples, the cover wafer (e.g., a glass wafer) 1101 may include a cover wafer window 1102 (or “unsupported window”), and a portion of the cover wafer 1101 may be removed. In some examples, the cover wafer window 1102 may be machined, while in other examples, the cover wafer window 1102 may be etched. It may be appreciated that a cover wafer window similar to the cover wafer window 1102 may be included in any of the examples described herein.

In some examples, the cover wafer 1101 may be attached to a housing layer 1105 via a metal bonding layer 1111a-b (e.g., similar to the example illustrated in FIG. 10). In some examples, the housing layer 1004 may include a waveguide 1006, and the waveguide 1006 may include a photonic integrated circuit.

In some examples, the housing layer 1105 may be provided on top of a base (e.g., silicon) substrate 1107. Also, in some examples, the base substrate 1107 may include an emission window 1108 that may be located below the cover wafer window 1102. In some examples, the emission window 1108 may be etched.

In some examples, the base substrate 1107 may include a through-wafer via element 1109 to provide an electrical coupling to a laser die 1103. That is, in some examples, the through-wafer via element 1109 may provide a connection through a base substrate 1107, rather than being placed on top of the base substrate 1107 (e.g., similar to the one or more etched pillars 708a, 708b in FIG. 7). In some examples, the laser die 1103 may include a laser cavity 1104.

In some examples, a silicon dioxide cladding element 1110 may be provided on top of the base substrate 1107, and a metal bonding layer 1111b may couple the silicon dioxide cladding element 1110 to the cover wafer 1101.

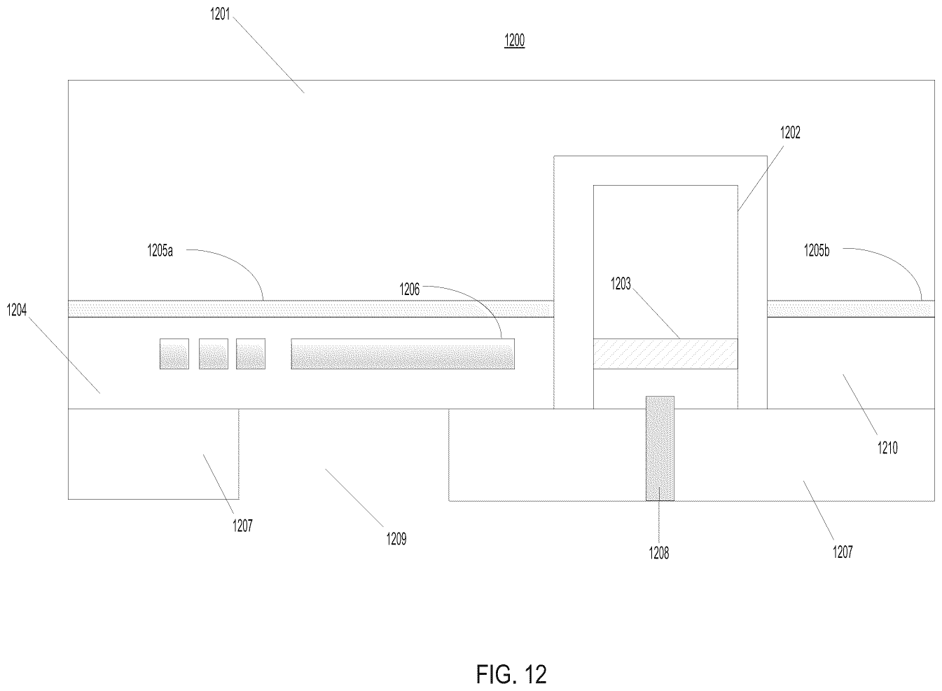

FIG. 12 illustrates a block diagram of an optical component 1200 including a hermetically-covered photonic integrated circuit having an epoxy bond, according to an example. In some examples, the optical component 1200 may include a cover wafer 1201. In some examples, the cover wafer 1201 may be composed of silicon dioxide (SiO₂).

In some examples, the cover wafer 1201 may be attached to a housing layer 1204 via an epoxy layer 1205a. In some examples, the epoxy layer 1205a may be transparent. In some examples, the housing layer 1204 may include a waveguide 1206, and the waveguide 1206 may include a photonic integrated circuit.

In some examples, the housing layer 1204 may be provided on top of a base substrate 1207. Also, in some examples, the base substrate 1207 may include an emission window 1209.

In some examples, the base substrate 1207 may include a through-wafer via element 1208 to provide an electrical coupling to a laser die 1202. That is, in some examples, the through-wafer via element 1208 may provide a connection through the base substrate 1207, rather than being placed on top of the base substrate 1207 (e.g., similar to the one or more etched pillars 708a, 708b in FIG. 7). In some examples, the laser die 1202 may include a laser cavity 1203.

In some examples, a silicon dioxide cladding element 1210 may be provided on top of the base substrate 1207, and an epoxy layer 1205b may couple the silicon dioxide cladding element 1210 to the cover wafer 1201.

In some instances, a window may change shape (or “open”) before or after a laser bonding process. That is, in some examples, it may be appreciated that a material (e.g., silicon nitride (SiN), silicon dioxide (SiO₂)) that may be used to provide a window as described herein may have a tendency to compress and thereby “wrinkle”. Also, in some instances, it may be appreciated that temperature and voltage conditions during fabrication (e.g., application and/or bonding of a cover glass) may cause deformities in a window as well. Accordingly, in some instances, it may be beneficial to select a material that may enable the window to not compress and otherwise remain maintain its shape (e.g., remain flat on its edges).

In some examples, it may be appreciated that a cover wafer may be composed of other materials than silicon dioxide (SiO₂), in which the materials may only be required to be transparent and/or thermally conductive. In some examples, a double window wafer (e.g., two windows composed of silicon) may be implemented, which may provide an option to put a complementary metal oxide semiconductor (CMOS) circuitry on top of a wafer. In some examples, a top wafer may also be composed of silicon or any non-transparent material with a strong absorbing layer on an interface surface, in order to eliminate back reflections in a “wrong” direction coming from a photonic integrated circuit.

In some examples, fabrication of a photonic integrated circuit on a non-transparent wafer, having enhanced thermal characteristics and broader fabrication compatibility options may be implemented.

In some examples, if a window etch process may be implemented with potassium hydroxide (KOH), this may be result in slanted sides having well-defined angles, which may then be used to set a separation of the liquid crystal on silicon (LCOS) surface to a photonic integrated circuit.

What has been described and illustrated herein are examples of the disclosure along with some variations. The terms, descriptions, and figures used herein are set forth by way of illustration only and are not meant as limitations. Many variations are possible within the scope of the disclosure, which is intended to be defined by the following claims—and their equivalents—in which all terms are meant in their broadest reasonable sense unless otherwise indicated.

1. An apparatus, comprising:
a housing layer comprising a waveguide, the waveguide including a photonic integrated circuit;
a laser die to implement at least one laser in conjunction with the photonic integrated circuit;
a cover wafer attached to the housing layer, the cover wafer to hermetically cover the photonic integrated circuit and the laser die; and
a base substrate attached to the laser die and the housing layer, the base substrate comprising a through-wafer via element coupled to the laser die to provide electrical coupling for the laser die.

2. The apparatus of claim 1, wherein the cover wafer comprises a pocket to house the laser die.

3. The apparatus of claim 1, wherein the cover wafer is attached to the housing layer via a transparent epoxy layer.

4. The apparatus of claim 1, wherein the cover wafer is attached to the housing layer via a bonding oxide layer.

5. The apparatus of claim 1, wherein the cover wafer is attached to the housing layer via a doped oxide layer.

6. The apparatus of claim 1, wherein the cover wafer is attached to the housing layer via a metal bonding layer.

7. The apparatus of claim 1, wherein the base substrate further comprises an emission window.

8. An apparatus, comprising:
a housing layer comprising a waveguide, the waveguide including a photonic integrated circuit;
a laser die to implement at least one laser in conjunction with the photonic integrated circuit;
a cover wafer attached to the housing layer, the cover wafer to provide hermetic covering to the photonic integrated circuit and the laser die;
a base substrate attached to the laser die and the housing layer, the base substrate comprising an emission window adjacent to the housing layer; and
a metal connection strip to electrically couple the laser die.

9. The apparatus of claim 8, further comprising at least one pillar located in a trench area of the base substrate to set a height of the laser die relative to the photonic integrated circuit.

10. The apparatus of claim 8, wherein the cover wafer comprises a pocket to house the laser die.

11. The apparatus of claim 8, wherein the laser die comprises a laser cavity.

12. The apparatus of claim 8, further comprising a silicon dioxide cladding element on top of the base substrate.

13. The apparatus of claim 12, wherein the metal connection strip is provided on top of the silicon dioxide cladding element and on top of the base substrate.

14. The apparatus of claim 12, wherein the cover wafer is attached to the housing layer and the silicon dioxide cladding element via a bonding oxide layer.

15. An apparatus, comprising:
a housing layer comprising a waveguide, the waveguide including a photonic integrated circuit;
a cover wafer attached to the housing layer, the cover wafer to provide hermetic covering to the photonic integrated circuit and a laser die;
a base substrate attached to the laser die and the housing layer, the base substrate comprising an emission window adjacent to the housing layer; and
a metal connection element coupled to the laser die.

16. The apparatus of claim 15, wherein the cover wafer comprises a pocket to house the laser die.

17. The apparatus of claim 15, wherein the cover wafer is attached to the housing layer via a bonding oxide layer.

18. The apparatus of claim 15, further comprising at least one pillar located in a trench area of the base substrate to set a height of the laser die relative to the photonic integrated circuit.

19. The apparatus of claim 18, wherein the metal connection element is provided in the trench area of the base substrate and adjacent to the at least one pillar.

20. The apparatus of claim 15, wherein the laser die comprises a laser cavity.
